(19) United States
(12) Patent Application Publication
(10) Pub. No.: US 2006/0220185 A1
(43) Pub. Date: Oct. 5, 2006

(54) Optical information storage medium

(75) Inventors: Hon-Lun Chen, Taipei Hsien (TW); Yuan-Chang Lai, Taipei Hsien (TW)

Correspondence Address: BIRCH STEWART KOLASCH & BIRCH, PO BOX 747, FALLS CHURCH, VA, 22040-0747, US

(73) Assignee: PRODISC TECHNOLOGY INC.

(21) Appl. No.: 11/135,381

(22) Filed: May 24, 2005

(30) Foreign Application Priority Data
Apr. 1, 2005 (TW) 094110638

(51) Int. Cl. H01L 23/58

(52) U.S. Cl. 257/635

(57) ABSTRACT

An optical information storage medium includes a first substrate, a first recording stack layer and a second substrate. The first recording stack layer is disposed above the first substrate. The second substrate is disposed above the first recording stack layer, and the hardness of the second substrate is higher than the first substrate.

### BACKGROUND OF THE INVENTION

1. Field of Invention

The present invention relates to an optical information storage medium and, in particular, to an optical information storage medium with better mechanical properties.

2. Related Art

Digital video disc (DVD) has different configuration such as single-side single-layer, dual-side single-layer, single-side dual-layer and dual-side dual-layer.

Conventionally, DVD may be manufactured by bonding process or photo-polymerization process. These two manufacturing process applied to DVD-R will respectively be illustrated herein below.

Bonding process: as shown in FIG. 1, a first recording layer 21 and a first reflective layer 22 are sequentially formed above a pre-grooved first substrate 10 to form a first recording stack layer 20 above the first substrate 10. A second reflective layer 41 and a second recording layer 42 are sequentially formed above a pre-grooved second substrate 30 to form a second recording stack layer 40 above the second substrate 30. Next, the first reflective layer 22 and the second recording layer 42 are bonded by a photo-setting resin to form a spacer layer (not shown) and the manufacturing processes are completed.

Photo-polymerization process: as shown in FIG. 2, a first recording layer 21 and a first reflective layer 22 are sequentially formed above a first substrate 10 to form a first recording stack layer 20 above the first substrate 10. Next, forming a photo-setting resin on a pre-grooved disc stamper and pressing the disc stamper onto the first reflective layer 22. By a photo curing, the photo-setting resin will be solidified to be a spacer layer 43. Then, removing the disc stamper and grooves will be formed on the spacer layer 43. A second recording layer 42 and a second reflective layer 41 are sequentially formed above the spacer layer 43 to form a second recording stack layer 40. Finally, forming a bonding layer (not shown) above the second reflective layer 41 to bond a second substrate 30 and the manufacturing processes are completed.

In the above-mentioned processes, the first reflective layer 22 and the second reflective layer 41 are formed by sputtering or evaporation. However, most of the first substrate 10 and the second substrate 30 are made of polycarbonate (PC). In bonding process, the mechanical property of the first substrate 10 and the second substrate 30 could not sustain high temperature during sputtering. It causes a bending issue to the first substrate 10 and the second substrate 30. In photo-polymerization process, the bending issue to the first substrate 10 will be caused not only by sputtering but also by removal of disc stamper. Some of the first substrate 10 and the second substrate 30 are made of polymethyl methacrylate (PMMA). Although the hardness of PMMA is higher than PC, however PMMA has disadvantage of moisture absorption.

It is therefore an important subject of the present invention to provide an optical information storage medium with better mechanical properties to raise production yield and quality.

### SUMMARY OF THE INVENTION

In view of the foregoing, the present invention is to provide an optical information storage medium for improving substrate bending issue and raising production yield.

To achieve the above, an optical information storage medium according to the present invention includes a first substrate, a first recording stack layer and a second substrate. The first recording stack layer is disposed above the first substrate. The second substrate is disposed above the first recording stack layer, and the hardness of the second substrate is higher than the first substrate.

As mentioned above, due to the hardness of the second substrate of an optical information storage medium according to the present invention is higher than the first substrate, substrate bending issue could be improved during the process. That is, an optical information storage medium according to the present invention could raise production yield and achieve the advantages of cost-down and high production efficiency.

### BRIEF DESCRIPTION OF THE DRAWINGS

The present invention will become more fully understood from the detailed description given herein below illustration only, and thus is not limitative of the present invention, and wherein:

FIG. 1 is a schematic view showing a conventional optical information storage medium;

FIG. 2 is a schematic view showing another conventional optical information storage medium;

FIG. 3 is a schematic view showing the first embodiment of an optical information storage medium according to the present invention;

FIG. 4 is another schematic view showing the first embodiment of an optical information storage medium according to the present invention;

FIG. 5 is a partial schematic view showing the second embodiment of an optical information storage medium according to the present invention;

FIG. 6 is a schematic view showing the second embodiment of an optical information storage medium according to the present invention;

FIG. 7 is a partial schematic view showing the third embodiment of an optical information storage medium according to the present invention; and

FIG. 8 is a schematic view showing the third embodiment of an optical information storage medium according to the present invention.

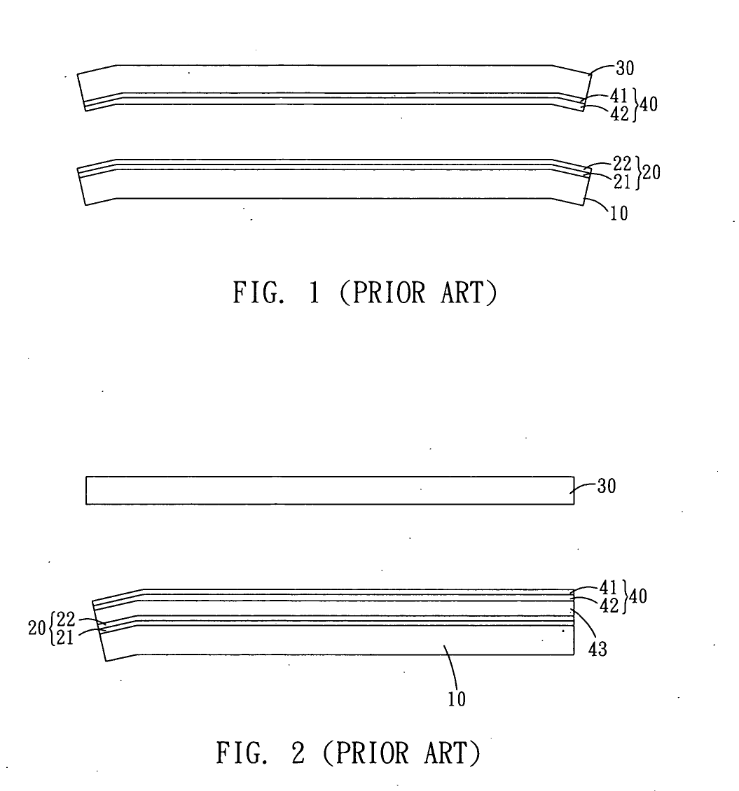

### DETAILED DESCRIPTION OF THE INVENTION

The present invention will be apparent from the following detailed description, which proceeds with reference to the accompanying drawings, wherein the same references relate to the same elements.

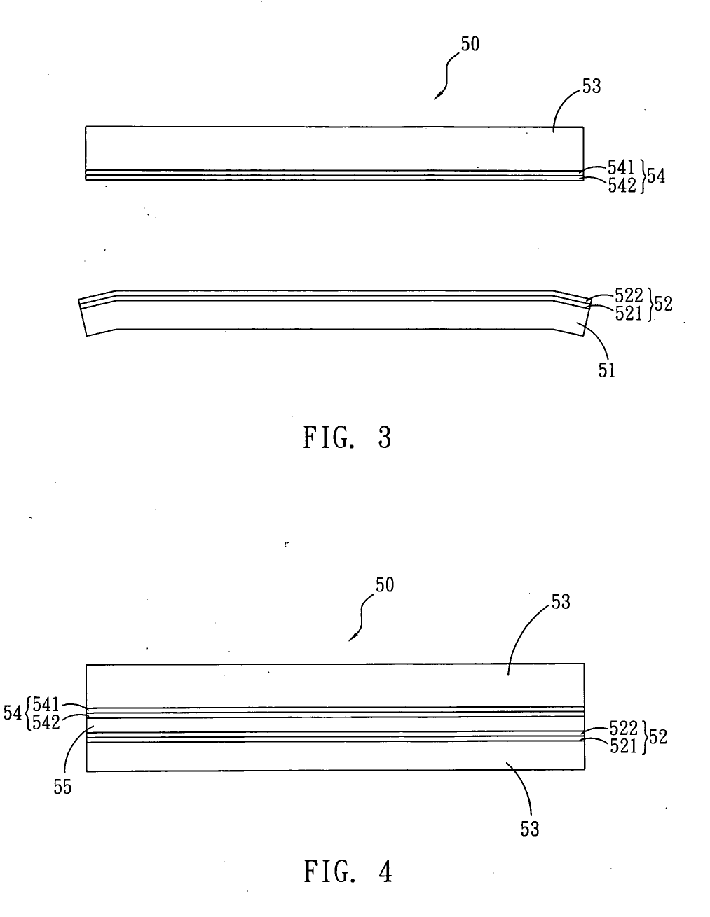

As shown in FIGS. 3 and 4, the first embodiment of an optical information storage medium 50 according to the present invention includes a first substrate 51, a first recording stack layer 52, a spacer layer 55, a second recording stack layer 54 and a second substrate 53. In this embodiment, the optical information storage medium 50 is manufactured by bonding process.

In this embodiment, the first substrate 51 is made of polycarbonate (PC) and its hardness is about 120, its tensile strength is about 65 MPa.

The first recording stack layer 52 is disposed above the first substrate 51. The first recording stack layer 52 includes a first recording layer 521 and a first reflective layer 522.

The hardness of the second substrate 53 is higher than the first substrate 51, and the transmittance ratio of the second substrate 53 ranges from 10% to 100% for penetrating by laser beam. When the first substrate 51 is made of polycarbonate (PC), for example the second substrate 53 may be made of liquid crystal polymer (LCP), the hardness of the second substrate 53 is higher than 120 and the tensile strength of the second substrate 53 is higher than 65 MPa. The material of the second substrate 53 may comprise acetal copolymer or nylon polymer.

As shown in FIG. 4, the spacer layer 55 and the second recording stack layer 54 are disposed between the first recording stack layer 52 and the second substrate 53.

The second recording stack layer 54 is disposed above the second substrate 53. The second recording stack layer 54 includes a second reflective layer 541 and a second recording layer 542 sequentially disposed above the second substrate 53. The spacer layer 55 is made of photo-setting resin and is disposed between the first reflective layer 522 of the first substrate 51 and the second recording layer 542 of the second substrate 53 to bond the first substrate 51 to the second substrate 53.

As shown in FIG. 3, due to the hardness of the first substrate 51 is less, the first substrate 51 would be bended during sputtering process. The hardness of the second substrate 53 is higher, it would keep a flat form during sputtering process. By bonding the first reflective layer 522 to the second recording layer 542, the second substrate 53 will make a compensation for the first substrate 51 and solve bending issue caused by sputtering.

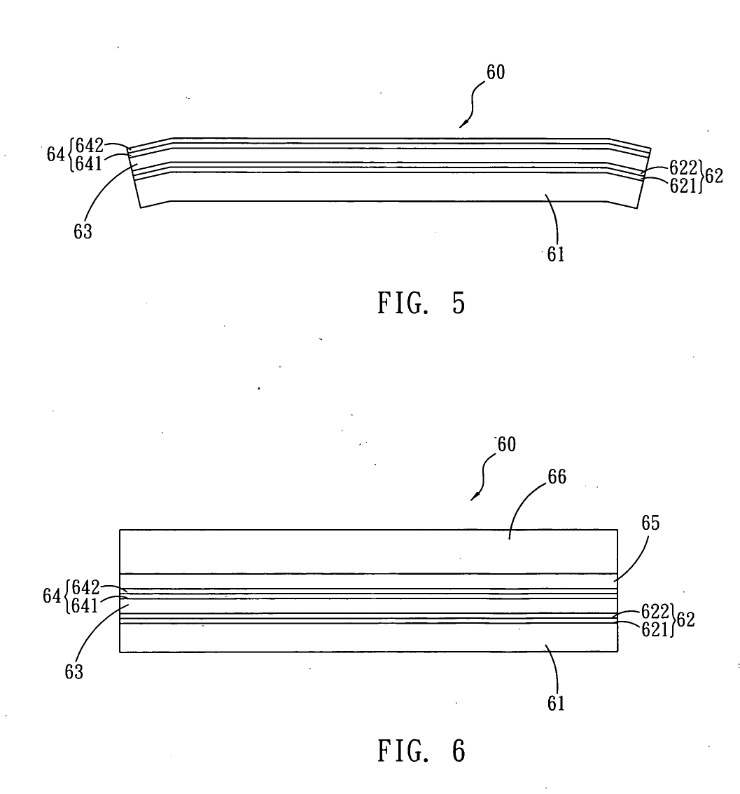

As shown in FIGS. 5 and 6, the second embodiment of an optical information storage medium 60 according to the present invention includes a first substrate 61 and a second substrate 66. In this embodiment, the optical information storage medium 60 is manufactured by photo-polymerization process.

A first recording stack layer 62 is disposed above the first substrate 61. The optical information storage medium 60 further comprises a spacer layer 63, a second recording stack layer 64 and a bonding layer 65 disposed between the first recording stack layer 62 and the second substrate 66.

As shown in FIG. 5, a first recording layer 621 and a first reflective layer 622 are sequentially disposed above the first substrate 61 to form the first recording stack layer 62 above the first substrate 61. Next, a photo-setting resin is formed on a disc stamper (not shown), and the disc stamper is pressed onto the first reflective layer 622. By a photo curing, the photo-setting resin is solidified to be a spacer layer 63. After removing the disc stamper, a second recording layer 641 and a second reflective layer 642 are sequentially formed above the spacer layer 63 to form a second recording stack layer 64 above the spacer layer 63. Finally, the bonding layer 65 is formed above the second reflective layer 642. By the bonding layer 65, the second reflective layer 642 is bonded to the second substrate 66 and the manufacturing processes of the optical information storage medium 60 are completed.

Due to the hardness of the second substrate 66 is higher than the first substrate 61, the first substrate 61 would be bended caused by sputtering process. By bonding the second substrate 66 to the first substrate 61, the second substrate 66 will make a compensation for the first substrate 61 and keep the optical information storage medium 60 to be a flat form.

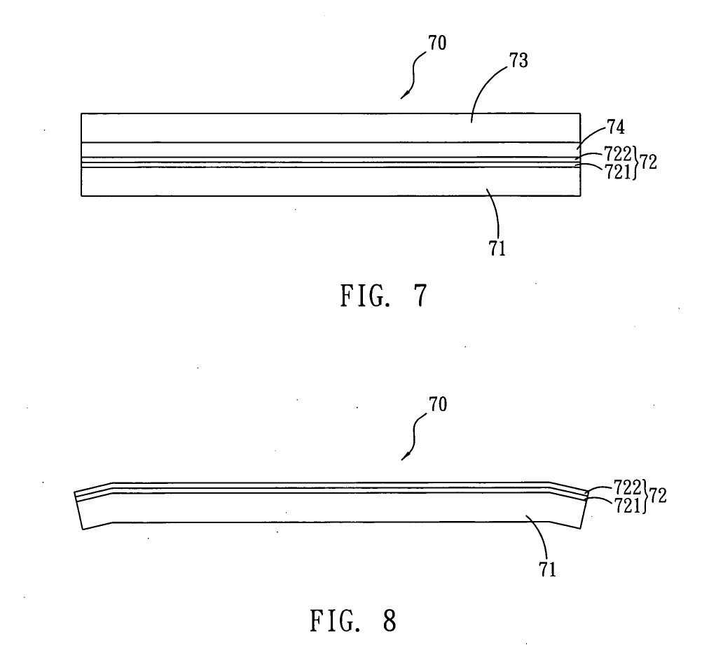

In previous embodiment, it is illustrated based on a single-side dual-layer DVD. Furthermore, the present invention may also be applied to manufacture a single-side single-layer DVD. As shown in FIGS. 7 and 8, the third embodiment of an optical information storage medium 70 according to the present invention includes a first substrate 71, a first recording stack layer 72 and a second substrate 73. A bonding layer 74 is disposed between the first recording stack layer 72 and the second substrate 73. Due to the mechanical properties such as hardness and tensile strength of the second substrate 73 is superior to the first substrate 71, the second substrate 73 also has an effect to make a compensation for the first substrate 71 and keep the optical information storage medium 70 to be a flat form.

In summary, due to the hardness of the second substrate of an optical information storage medium according to the present invention is higher than the first substrate, substrate bending issue could be improved during the process. That is, an optical information storage medium according to the present invention could raise production yield and achieve the advantages of cost-down and high production efficiency.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

1. An optical information storage medium, comprising:
a first substrate;
a first recording stack layer, disposed above the first substrate;and
a second substrate, disposed above the first recording stack layer and the hardness of the second substrate is higher than the first substrate.

2. An optical information storage medium according to claim 1, wherein the material of the first substrate comprises polycarbonate.

3. An optical information storage medium according to claim 2, wherein the hardness of the second substrate is higher than polycarbonate.

4. An optical information storage medium according to claim 1, wherein the hardness of the second substrate is higher than 120.

5. An optical information storage medium according to claim 1, wherein the tensile strength of the second substrate is higher than 65 MPa.

6. An optical information storage medium according to claim 1, wherein the transmittance ratio of the second substrate ranges from 10% to 100%.

7. An optical information storage medium according to claim 1, further comprising
a bonding layer, disposed between the first recording stack layer and the second substrate.

8. An optical information storage medium according to claim 1, further comprising
a spacer layer, a second recording stack layer and a bonding layer, disposed between the first recording stack layer and the second substrate.

9. An optical information storage medium according to claim 1, further comprising
a spacer layer and a second recording stack layer, disposed between the first recording stack layer and the second substrate.

10. An optical information storage medium according to claim 1, wherein the material of the second substrate comprises liquid crystal polymer.

11. An optical information storage medium according to claim 1, wherein the material of the second substrate comprises acetal copolymer.

12. An optical information storage medium according to claim 1, wherein the material of the second substrate comprises nylon polymer.

13. An optical information storage medium according to claim 1, wherein the storage medium is single-side single-layer DVD.

14. An optical information storage medium according to claim 1, wherein the storage medium is single-side dual-layer DVD.
